(19) United States
(12) Patent Application Publication
(10) Pub. No.: US 2024/0184933 A1
(43) Pub. Date: Jun. 6, 2024

(54) SYSTEM AND METHOD FOR INFORMATION TECHNOLOGY (IT) INFRASTRUCTURE SURVEYING AND INVENTORY MANAGEMENT

(71) Applicant: SAUDI ARABIAN OIL COMPANY, Dhahran (SA)

(72) Inventor: Muhammed Fahad ATHAR, Al-Rakkah (SA)

(73) Assignee: SAUDI ARABIAN OIL COMPANY, Dhahran (SA)

(21) Appl. No.: 18/060,870

(22) Filed: Dec. 1, 2022

(51) Int. Cl. G06F 30/12; G06F 16/29; G06V 10/764; H04W 4/021

(52) U.S. Cl. CPC G06F 30/12; G06F 16/29; G06V 10/764; H04W 4/021

(57) ABSTRACT

An information technology (IT) infrastructure survey and inventory management (SIM) system is described herein. A portable device of the system is configured with a site surveyor that can communicate location information for the device during a site survey of IT equipment of the IT infrastructure to a geospatial inventory database of the system. This database can provide geo-location data for the IT infrastructure and/or site based on the location information to the portable device for rendering therein. The site surveyor can cause a camera of the portable device to capture at least one image of the IT equipment. The system includes an image processing database with a machine learning (ML) model that can output IT equipment data based on the one or more images. The geospatial inventory database can map the IT equipment data to an IT record to update the IT record for the IT infrastructure and/or site.

### FIELD OF THE DISCLOSURE

This disclosure relates generally to site surveying, and more particularly, to a system and method for optimizing information technology (IT) site surveying and inventory management.

### BACKGROUND OF THE DISCLOSURE

Information technology (IT) infrastructure is defined broadly as a set of information technology (IT) components that are the foundation of an IT service. IT infrastructure can be deployed within a cloud computing system, or within an organization's own facilities. An IT infrastructure typically includes hardware (e.g., servers, datacenters, personal computers, routers, switches, and other equipment), software (e.g., applications used by an organization, such as web servers, content management systems, an operating system (OS), etc.), and networking (e.g., interconnected network components that enable network operations, management, and communication between internal and external systems). Common IT infrastructures include traditional infrastructures, software-defined, infrastructure-as-a-service, composable, cloud infrastructures, converged and hyperconverged infrastructures. Based on a type of IT infrastructure deployed, management of these architectures can include OS management, cloud management, virtualization management. IT operations management, IT automation, container orchestration, configuration management, application program interface (API) management, risk management, and data management.

### SUMMARY OF THE DISCLOSURE

Various details of the present disclosure are hereinafter summarized to provide a basic understanding. This summary is not an extensive overview of the disclosure and is neither intended to identify certain elements of the disclosure nor to delineate the scope thereof. Rather, the primary purpose of this summary is to present some concepts of the disclosure in a simplified form prior to the more detailed description that is presented hereinafter.

According to an embodiment, a computer implemented method can receive, by one or more processors, location information for a portable device located at a site having an IT infrastructure with IT equipment, identifying, by the one or more processors, geo-location data for the IT infrastructure and/or site based on the location information, receiving, by the one or more processors, IT equipment data generated by a machine learning (ML) model based on one or more images of the IT equipment, and mapping, by the one or more processors, the IT equipment data to an IT record to update the IT record for the site and/or IT infrastructure.

In another embodiment, a system can include memory to store machine-readable instructions and data, and one or more processors to access the memory and execute the machine-readable instructions. The machine-readable instructions can include a site surveyor that causes a network interface of a portable device to communicate location information for the portable device to a geospatial inventory database hosted by a computing system. The geospatial inventory database can be configured to provide the site surveyor with geo-location data for an IT infrastructure and/or site with IT equipment based on the location information of the portable device. The site surveyor further renders the geo-location data on a display of the portable device, and causes a camera of the mobile device to capture one or more images of the IT equipment. The system further comprises an image processing database that includes a ML model that processes the one or more images of the IT equipment to identify IT equipment information therein, generates IT equipment data using the identified IT equipment information, and causes an IT record of the geospatial inventory database for the site and/or IT infrastructure to be updated based on the IT equipment data.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is an example of an IT infrastructure survey and inventory management (SIM) system.

FIG. 2 is an example of a method for IT inventory management.

FIG. 3 is an example of a method for IT infrastructure surveying and inventory management.

FIG. 4 is an example of another method for IT infrastructure surveying and inventory management.

FIG. 5 is an example of a graphical user interface (GUI) of an attribute editor.

FIG. 6 is an example of a CAD drawing.

FIG. 7 is an example of another method for IT infrastructure surveying and inventory management.

FIG. 8 depicts an example computing environment that can be used to perform methods according to an aspect of the present disclosure.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments in accordance with the present disclosure generally relate to IT infrastructure surveying and inventory management. Organizations planning a new IT project or updating an existing IT project require that personnel go out into the field to gather IT infrastructure information (e.g., number of servers, server locations, type of servers, connections, etc.). Once on site, the personnel have to manually record the IT infrastructure information for IT equipment, which is a time-consuming and costly process for an organization, as well as prone to human error. After recording the IT infrastructure information, the personnel have to update a repository/database with the relevant information for the IT project.

According to the examples herein, an IT infrastructure SIM (Survey and Inventory Management) system is described that simplifies and improves an overall efficiency of IT project planning/updating and inventory management. The IT infrastructure SIM system can automatically identify a location of a site (e.g., a building) once personnel are on site, IT equipment details, and update an IT record or object for IT equipment in a database, which may be stored at a remote computing system. In some instances, the IT infrastructure SIM system can provide a graphical model of the IT equipment, which can be used for IT infrastructure planning.

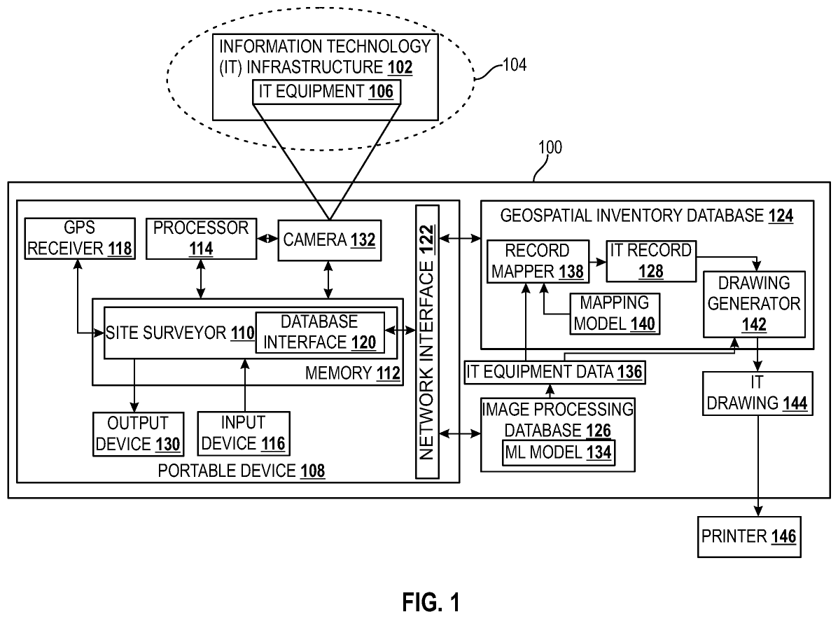

FIG. 1 is a block diagram of an IT infrastructure SIM system 100 in accordance with certain embodiments. The system 100 can be used to inspect and inventory an IT infrastructure 102 at a site 104 to capture IT equipment information for IT project planning or implementation. In some instances, the site 104 is a building and includes an IT room, such as a server room, for example, for a telecommunications entity. In further examples, the site 104 is one or more entire buildings or stations devoted to IT, such as a data center. In some examples, the site 104 can be referred to as the IT room. The IT infrastructure 102 can include a number of IT equipment 106. For example, the IT equipment 106 can include racks, cabinets, servers, networking equipment and appliances, power supplies, cables, etc. Examples are presented herein in which the system 100 is used for surveying IT equipment and IT inventory management. However, it is be to be understood that the system 100 can be used for any type of equipment surveying and inventory management.

Continuing with the example of FIG. 1, the IT infrastructure SIM system 100 includes a portable device 108 that can be configured with a site surveyor 110. The portable device 108 can include any computing device that can be transported or carried by a user, for example, a mobile phone, a tablet, a laptop, a personal digital assistant (PDA), a tablet, and the like. The site surveyor 110 can be implemented using one or more modules, shown in block form in the drawings. The one or more modules can be in software or hardware form, or a combination thereof. In some examples, the site surveyor 110 can be implemented as machine readable instructions that can be stored in a memory 112, as shown in FIG. 1. A processor 114 can access a memory 112 and execute machine readable instructions stored therein to implement at least some of the functions as described herein.

By way of example, the memory 112 can be implemented, for example, as a non-transitory computer storage medium, such as volatile memory (e.g., random access memory (RAM), such as DRAM), non-volatile memory (e.g., a hard disk drive, a solid-state drive, a flash memory, or the like), or a combination thereof. The processor 114 can be implemented, for example, as one or more processor cores. In some instances, the site surveyor 110 can be implemented as an application that can be installed on the portable device 108, and executed by the user in response to user input at an input device 116 of the portable device 108. For example, once the user is located on the site 104 the user can employ the input device 116 to initiate the site surveyor 110 for surveying the IT infrastructure 102. As an example, the input device 116 is a keyboard, a touchpad, a mouse, a touch-screen display, etc.

The site surveyor 110 can communicate with a global position system (GPS) receiver 118 of the portable device 108 to request location information (e.g., GPS coordinates) for the portable device 108. In some examples, a different type of location determination device can be used instead of GPS. The GPS receiver 118 can provide the location information in response to a location request from the site surveyor 110. Thus, a location of the portable device 108 can be automatically determined in response to the site surveyor 110, which can be initiated automatically or by the user once the user is on the site 104. The site surveyor 110 includes a database interface 120, which can use a network interface 122 of the portable device 108 to communicate with a geospatial inventory database 124 and an image processing database 126. The network interface 122 enables the portable device 108 to communicate over a wired and/or wireless network with each of the databases 124 and 126. Each of the databases 124 and 126 can be implemented on a similar or a different computing platform. The computing platform could be implemented in a computing cloud. In such an arrangement, features of the computing platform could be representative of a single instance of hardware or multiple instances of hardware with the databases 124 and 126 executing across the multiple of instances (e.g., distributed) of hardware (e.g., computers, routers, memory, processors, or a combination thereof). Alternatively, the computing platform could be implemented on a single dedicated server or workstation.

The database interface 120 can communicate the requested location information to the geospatial inventory database 124. The geospatial inventory database 124 can process the requested location information to identify geo-location data associated (e.g., logically linked in memory) with an IT record 128 for the IT infrastructure 102 and/or site 104. For example, the geospatial inventory database 124 can include geofence data characterizing geofences for a number of different sites, including the site 104. The geospatial inventory database 124 can compare the location information to the geofences to determine whether if any of the geofences include the location information. If the location information is within a geofence for the site 104, the geospatial inventory database 124 can identify the geo-location data for the IT record 128 for the IT infrastructure 102 and/or site 104. In some instances, the IT record 128 includes geofence data and/or the geo-location data for the site 104.

While information/data is described herein as being stored at the geospatial inventory database 124 in an IT record, in other examples, a different information/data organizational structure or schema can be used to structure, record and/or track relevant data, as described herein. In some examples, the geospatial inventor database 124 is part of or corresponds to a geographic information system (GIS) system. The GIS can be capable of documenting (e.g., managing) IT inventory. In some examples, the GIS can be implemented as an ArcGIS from Environmental Systems Research Institute (ESRI). Thus, in some instances, the geospatial inventory database 124 can be referred to as a GIS database. In some examples, the geospatial inventory database 124 can include a control and reference functionality, which can be used to define policy and procedure, and create a library of IT equipment corresponding to the IT record 128 for visualization for each site and/or IT infrastructure, including the IT infrastructure 102 and/or site 104. The geospatial inventory database 124 can also include IT inventory editing functionality to view and edit IT inventory for IT infrastructure, such as the IT infrastructure 102. For example, the IT inventory editing functionality can be invoked, in some instances, automatically in response to determining that the IT infrastructure 102 and/or site 104 includes different IT equipment than that stored in the IT record 128 for the IT infrastructure 102 and/or site 104.

The geospatial inventory database 124 can return the geo-location data to the database interface 120 based on the location information. The geo-location data can include, for example, a site name, a floor plan, a number of floors, a number of IT rooms, a number of IT racks, a site address, an IT room number, and other geolocation-based information. In some examples, referred to herein as “a given example,” the IT record 128 for the IT infrastructure does not include the geo-location information. In the given example, the site surveyor 110 can generate a GUI on an output device 130 to request that the user of the portable device 108 manually enter the site name, site address, and/or the IT room number to provide the geo-location data. The output device 130 can include a display, for example a touch-screen display. In the given example, the geo-location data can be communicated to the geospatial inventory database 124 and stored as part of a corresponding IT record for the IT infrastructure 102 and/or site 104.

The user can employ the site surveyor 110 to capture IT equipment information for the IT equipment 106. For example, the user can employ the site surveyor 110 to initiate a camera 132 of the portable device 108. The camera 132 can be used to capture one or more images of the IT equipment 106. For example, the one or more images of the IT equipment 106 can include a front and/or a back end of the IT equipment 106. One or more labels can be located on the IT equipment 106 and thus captured in the one or more images. The one or more labels can for example be in the form of a machine-readable code (e.g. barcode or QR code) and include information corresponding to at least some of the captured IT information. For example, the captured IT equipment information can include a number of devices (e.g., servers), device type, a rack number, a manufacturer, a model, connections, and other types of equipment information. In some examples, the one or more images of the IT equipment 106 can include wires, which can be processed by the image processing database 126 to determine a number of wires and wire type and wire connections.

In some examples, the database interface 120 can provide the one or more images of the IT equipment 106 to the image processing database 126. In some implementations, the database interface 120 can provide IT infrastructure or site information identifying the IT infrastructure 102 or the site 104 to the image processing database 126. The image processing database 126 can communicate the IT infrastructure or site information with or as part of the IT equipment data 136 to the geospatial inventory database 124, which can use the IT infrastructure or site information to identify that the IT equipment data 136 is for the IT infrastructure 102 for updating the IT record 128. The image processing database 126 can include a ML (Machine Learning) model 134 that is trained to extract IT equipment information from the one or more images. For example, the ML model 134 can process the one or more images to provide IT equipment data 136, which includes the IT equipment information extracted from therein.

The ML model 134 can be generated using a supervised, unsupervised, and/or a reinforced ML algorithm, or a different type of ML algorithm. In some instances, the image processing database 126 includes a ML trainer that can employ a ML algorithm to train the ML model 134 for image recognition/classification. In other examples, the ML trainer is executed on a different device on which the image processing database 126 is executed for training the ML model 134. Examples of ML algorithms can include a random forest classifier algorithm, a k-nearest neighbor (KNN) algorithm, a decision tree classifier algorithm, an artificial neural network (ANN) algorithm (e.g., a deep neural network (DNN), a convolution neural network (CNN), learning vector quantization, etc.), and a Naïve Bayes classifier. By way of further example, the image processing database 126 or a different database can include image training data, which can include a number of captured images of IT equipment across a number of sites. In some examples, the images of the IT equipment of the image training data can include tags or labels (e.g., identifying features within the images). For example, the ML trainer can uses semantic segmentation to train the ML model 134 based on the image training data.

The IT equipment data 136 can be provided to the geospatial inventory database 124, as shown in FIG. 1. In some examples, the IT equipment data 136 is provided to the database interface 120. The site surveyor 110 can output on the output device 130 a GUI with the IT equipment information from the IT equipment data 136. In further examples, the database interface 120 can provide the IT equipment data 136 to the geospatial inventory database 124. The geospatial inventory database 124 can include a record mapper 138. The record mapper 138 can map the IT equipment data 136 to the IT record 128 for the IT infrastructure 102. For example, the record mapper 138 can map the IT equipment data 136 to a data object based on a mapping model 140. The mapping model 140 can define or contain information for a relationship between source and target schemas. Thus, the record mapper 138 can map the IT information from the IT equipment data 136 to respective targets (e.g., fields, memory location, etc.) of the IT record 128. In some examples, the record mapper 138 can create an inventory object or update an existing inventory object of the IT record 128 during the mapping. By way of further example, the geospatial inventory database 124 can include a model builder, which can be used by a user to construct or generate the record mapper 138, and thus define how the IT equipment data 136 is processed (e.g., mapped) at the geospatial inventory database 124 to update or change the IT record 128.

In some examples, the geospatial inventory database 124 includes a drawing generator 142. The drawing generator 142 can process relevant data from the IT record 128 to generate an IT drawing 144 for the IT equipment 106. The IT drawing 144 can be a visual depiction of the IT equipment 106 with IT equipment information from the IT record 128. In some examples, the IT drawing 144 is a computer-aided design (CAD) drawing. The IT drawing 144 can be sent to a printer 146 for rendering the IT drawing 144 on one or more papers (e.g., special fine paper, such as ink jet paper). Thus, in some instances, the drawing generator 142 can interface with the printer 146 and cause the printer 146 to render the IT drawing 144 on the one or more pages. In some examples, the printer 146 is part of the IT infrastructure SIM system 100.

In some instances, the IT equipment data 136 can identify image locations for labels located on the IT equipment 106 in the one or more images received from the portable device 108. The drawing generator 142 can include corresponding drawing labels representative of the labels in the one or more images at locations in the visual depiction of the IT equipment 106 that is similar or matches the ones specified by the IT equipment data 136. Therefore, in some examples, the drawing generator 142 can receive the IT equipment data 136 and use relevant data therein for generating the IT drawing 144.

Accordingly, the IT infrastructure SIM system 100 simplifies and improves an overall efficiency of IT project planning/updating and thus IT equipment management, such as the IT equipment 106. The IT infrastructure SIM system 100 can automatically identify a location of the site 104 (e.g., a building) once personnel are on site, IT equipment details at the site 104, and update the IT record 128 for the IT infrastructure 102 stored at the geospatial inventory database 124. In some instances, the IT infrastructure SIM system 100 can provide a graphical model of the IT equipment 106 corresponding to the IT drawing 144, which can be used for IT infrastructure planning and management.

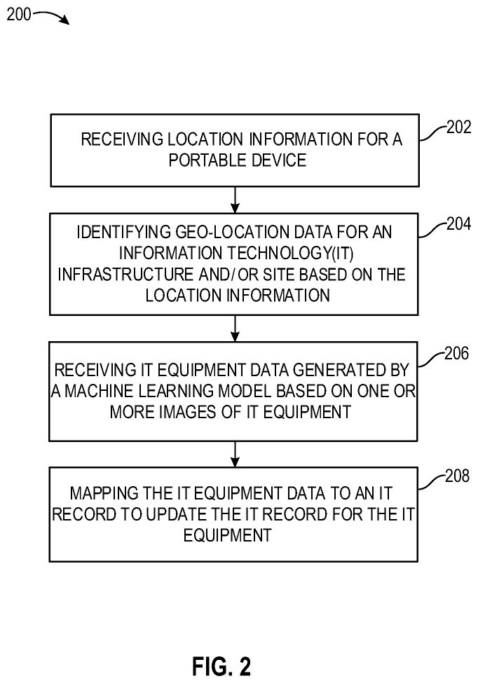

In view of the foregoing structural and functional features described above, an example method will be better appreciated with reference to FIGS. 2-4. While, for purposes of simplicity of explanation, the example methods of FIGS. 2-4 are shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement the methods.

FIG. 2 is an example of a method 200 for IT inventory management. The method 200 can be implemented by the geospatial inventory database 124, as shown in FIG. 1. Thus, reference can be made to the example of FIG. 1 in the example of FIG. 2. The method 200 can begin at 202 by receiving location information (e.g., GPS coordinates) for a portable device (e.g., the portable device 108, as shown in FIG. 1). At 204, identifying geo-location data for an IT infrastructure and/or site (e.g., the IT infrastructure 102 and/or the site 104, as shown in FIG. 1) based on the location information is performed. At 206, receiving IT equipment data (e.g., the IT equipment data 136, as shown in FIG. 1) generated by a ML model (e.g., the ML model 134, as shown in FIG. 1) based on one or more images of IT equipment (e.g., the IT equipment 106, as shown in FIG. 1) of the IT infrastructure is performed. The one or more images of the IT equipment can be captured by a camera (e.g., the camera 132, as shown in FIG. 1) of the portable device during an IT equipment or infrastructure survey, although other types of detectors, such as RFID tag readers, are also contemplated. At 208, mapping (e.g., by the recorder mapper 138, as shown in FIG. 1), the IT equipment data to an IT record (e.g., the IT record 128, as shown in FIG. 1) to update the IT record for the site is performed. In some examples, an IT drawing (e.g., the IT drawing 144, as shown in FIG. 1) can be generated (e.g., by a drawing generator 142, as shown in FIG. 1) based on the updated IT record. In further examples, a printer (e.g., the printer 146, as shown in FIG. 1) can be caused (e.g., by the drawing generator 142) to print the IT drawing on one more papers.

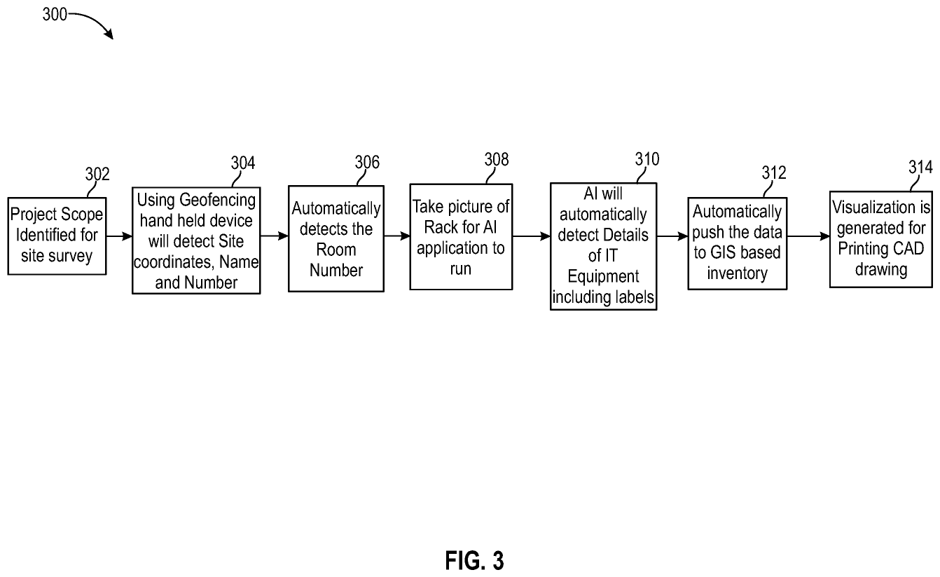

FIG. 3 is an example of a method 300 for IT infrastructure surveying and inventory management in accordance with certain embodiments. At least some of the method 300 can be implemented by the infrastructure SIM system 100, as shown in FIG. 1. Thus, reference can be made to the example of FIG. 1 in the example of FIG. 3. The method 300 can begin at 302 by identifying a project scope for a site survey of an IT room, which can include identifying a building that includes the IT room (e.g., location information for a building that includes the IT room), and/or building information (e.g., building name or address). At 304, determining a location of a portable device (e.g., the portable device 108, as shown in FIG. 1) is performed. The location of the portable device can be determined using geofencing, which can be implemented in some instances at the portable device, and, in other instances, at a geospatial inventory database (e.g., a geospatial inventory database 124, as shown in FIG. 1) based on location information determined (e.g., by the GPS receiver 118, as shown in FIG. 1) for the portable device. The determined location of the portable device can include coordinates (e.g., GPS coordinates) corresponding to a site (e.g., the site 104, as shown in FIG. 1) that includes the IT room.

At 306, a room number for an IT room of the site is detected. In some instances, the detecting of the room number can be done automatically based on the location of the portable device. For example, the portable device can communicate with the geospatial inventory database to receive the room number for the IT room, which can be rendered on an output device (e.g., the output device 130, as shown in FIG. 1) for a user of the portable device. At 308, activating a camera (e.g., the camera 132, as shown in FIG. 1) or similar detector of the portable device to capture one or more images or other information of IT equipment (e.g., the IT equipment 106, as shown in FIG. 1) in the IT room for ML processing is performed. At 310, processing using a ML model (e.g., the ML model 134, as shown in FIG. 1) the one or more images to detect IT equipment information therein is performed. In some examples, the detected IT equipment information includes equipment labels. At 312, providing the detected IT equipment information as IT equipment data (e.g., the IT equipment data 136, as shown in FIG. 1) to a GIS database (e.g., the geospatial inventory database 124, as shown in FIG. 1). At 314, generating an IT drawing (e.g., the IT drawing 144, as shown in FIG. 1) corresponding to a CAD drawing for printing at a printer (e.g., the printer 146, as shown in FIG. 1) is performed.

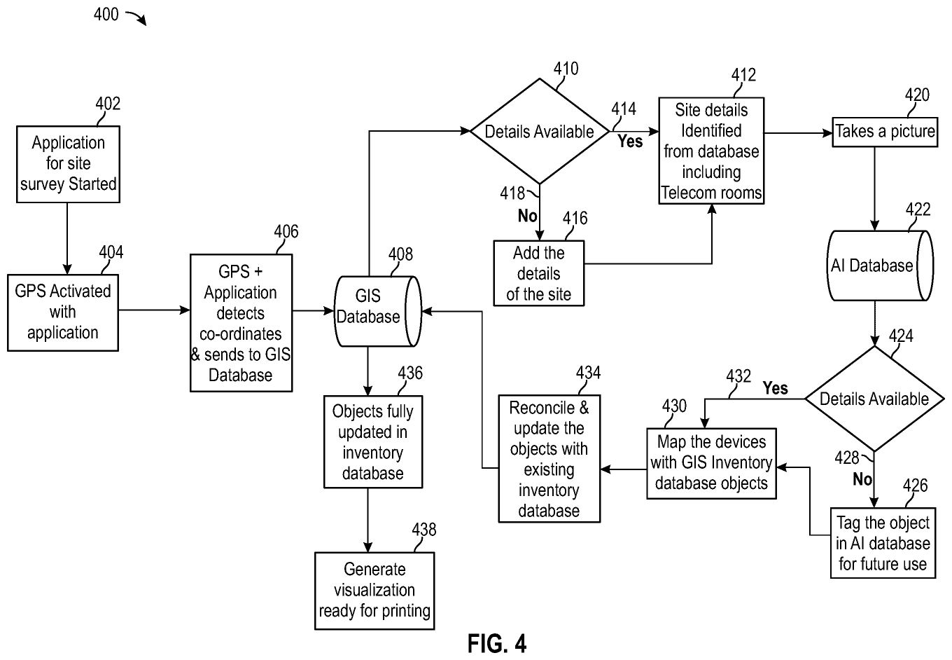

FIG. 4 is an example of another method 400 for IT infrastructure surveying and inventory management. At least some of the method 400 can be implemented by the infrastructure SIM system 100, as shown in FIG. 1. Thus, reference can be made to the example of FIG. 1 in the example of FIG. 4. The method 400 can begin at 402 by identifying a project scope for a site survey of an IT room, which can include identifying a building that includes the IT room (e.g., location information for a building that includes the IT room), and/or building information (e.g., building name or address). At 404, activating (manually or automatically) a GPS receiver (e.g., the GPS receiver 118, as shown in FIG. 1) of a portable device (e.g. the portable device 108, as shown in FIG. 1) in response to a site surveyor (e.g., the site surveyor 110, as shown in FIG. 1) executing on the portable device is performed. At 406, receiving location information (e.g., GPS coordinates) from the GPS receiver and communicating using a database interface (e.g., the database interface 120, as shown in FIG. 1) of the site surveyor the location information to a GIS database 408 is performed. In some examples, the GIS database 408 includes or corresponds to a geospatial inventory database (e.g., the geospatial inventory database 124, as shown in FIG. 1).

At 410, determining (e.g., by the GIS database 408) if geo-spatial data for an IT infrastructure and/or site (e.g., the IT infrastructure 102 and/or the site 104) exists in the GIS database is performed. In some examples, at 412, transmitting (e.g., by the GIS database 408) the geospatial data to the portable device in response to determining that the geo-spatial data exists therein, shown with a “Yes” at 414 in the example of FIG. 4, is performed. In some examples, at 416 requesting from a user of the portable device information/details for the IT infrastructure and/or site in response to determining that the geo-spatial data does not exist therein, shown with a “No” at 418 in the example of FIG. 4 is performed.

At 420, the method 400 includes taking (e.g., capturing) one or more pictures or other information of IT equipment (e.g., the IT equipment 106, as shown in FIG. 1) in an IT room for ML processing at an artificial intelligence (AI) database 422. The AI database 422 can include or correspond to the image processing database 126, as shown in FIG. 1. At 424, determining using a ML model (e.g., the ML model 134, as shown in FIG. 1) of the AI database 420 whether the one or more pictures contain IT equipment information is performed. At 426, tagging features or objects in the one or more pictures as newly discovered or detected IT equipment information in response to determining that the one or more pictures contain new information, shown at 428 with a “No” in the example of FIG. 4 is performed. In some instances, at 426, updating the ML model so that the ML model can capture the newly discovered or detected IT equipment information in future pictures or images of IT equipment is performed.

In some instances, at 430, generating IT equipment data (e.g., the IT equipment data 136, as shown in FIG. 1) based on the one more pictures, in some instances, in response to detecting the equipment information therein, shown at 432 with a “Yes” in the example of FIG. 4, is performed. In some examples the IT equipment data is generated based on the newly discovered or detected IT equipment. At 434, reconciling and updating an inventory object for the IT equipment in the GIS database 408 is performed. The reconciling can include comparing the IT equipment data relative to the inventory object to identify differences and updating the inventory object to reflect the identified differences. In some instances, the inventory object is part of or corresponds to an IT record (e.g., the IT record 128, as shown in FIG. 1). In further examples, at 436, storing the updated inventory object or IT record in memory for visualization is performed. At 436, generating (e.g., by the drawing generator 142, as shown in FIG. 1) a visualization (e.g., the IT drawing 144, as shown in FIG. 1) based on the stored updated inventory object for printing (e.g., by the printer 146, as shown in FIG. 1) is performed.

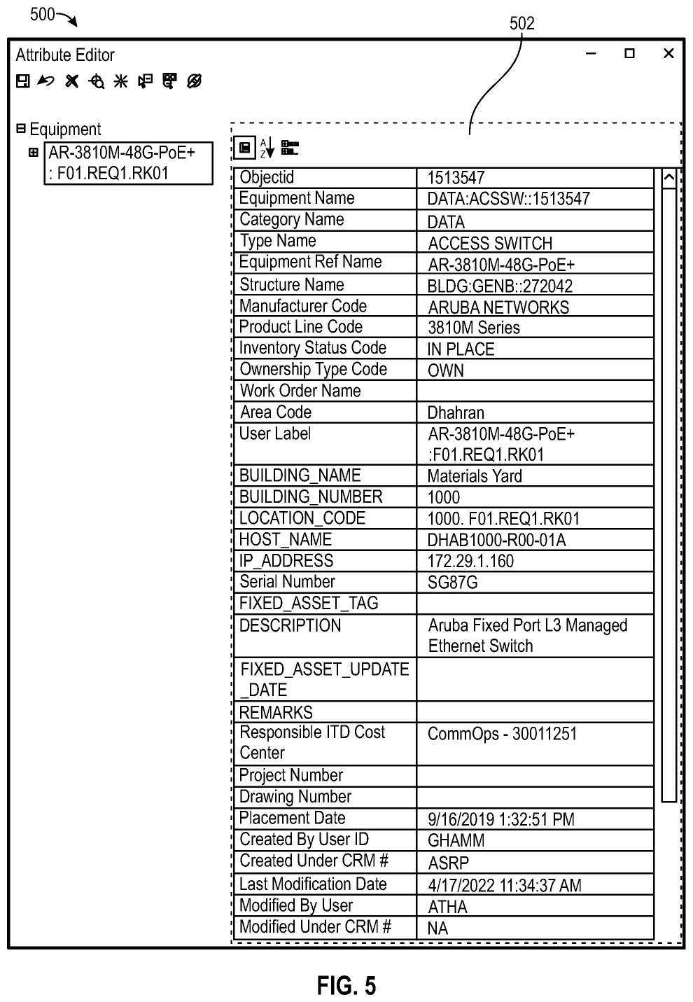

FIG. 5 is an example of a GUI of an attribute editor 500. The attributor editor 500 can be generated by a GIS, which can include or correspond to the geospatial inventory database 124, as shown in FIG. 1. Thus, reference can be made to the example of FIG. 1 in the example of FIG. 5. The attribute editor 500 can render an inventory object window 502. In some examples, the attribute editor 500 can receive from the recorder mapper 138 the inventory object for rendering the inventory object window 502. In some instances, the attribute editor 500 can cooperate with the recorder mapper 138 to generate the inventory object window 502 based on the inventory object. As shown in the example of FIG. 5, the inventory object window 502 includes IT inventory information/details for IT equipment (e.g., the IT equipment 106, as shown in FIG. 1).

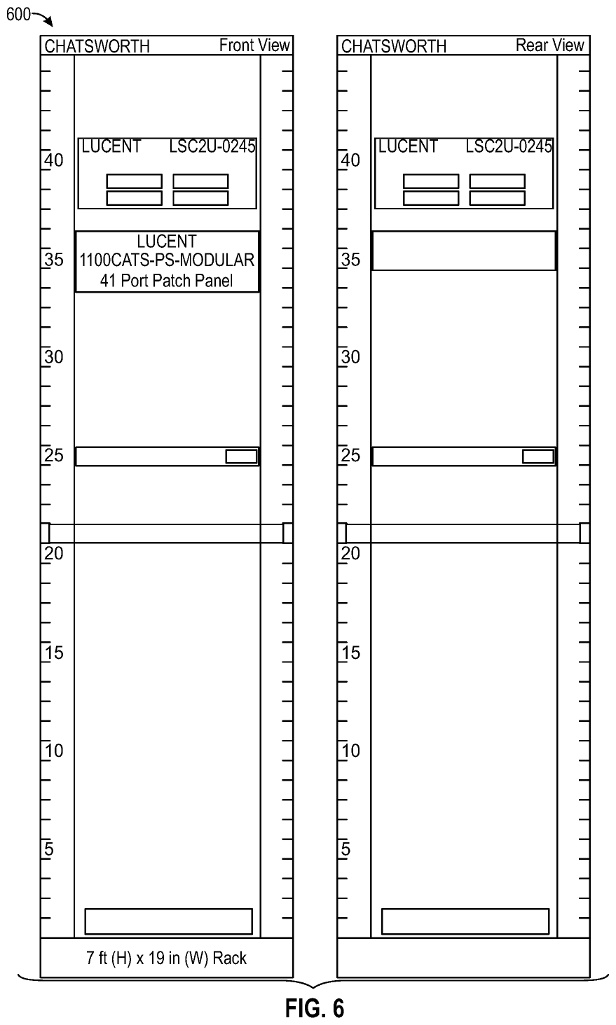

FIG. 6 is an example of a CAD drawing 600. The CAD drawing 600 can be rendered according to the examples described herein. Thus, reference can be made to the example of FIG. 1 in the example of FIG. 6. For example, the CAD drawing 600 can be rendered by the drawing generator 142 based on the IT record 128, and in some instances, as well as on the IT equipment data 136 that is provided by the ML model 134 of the image processing database 126.

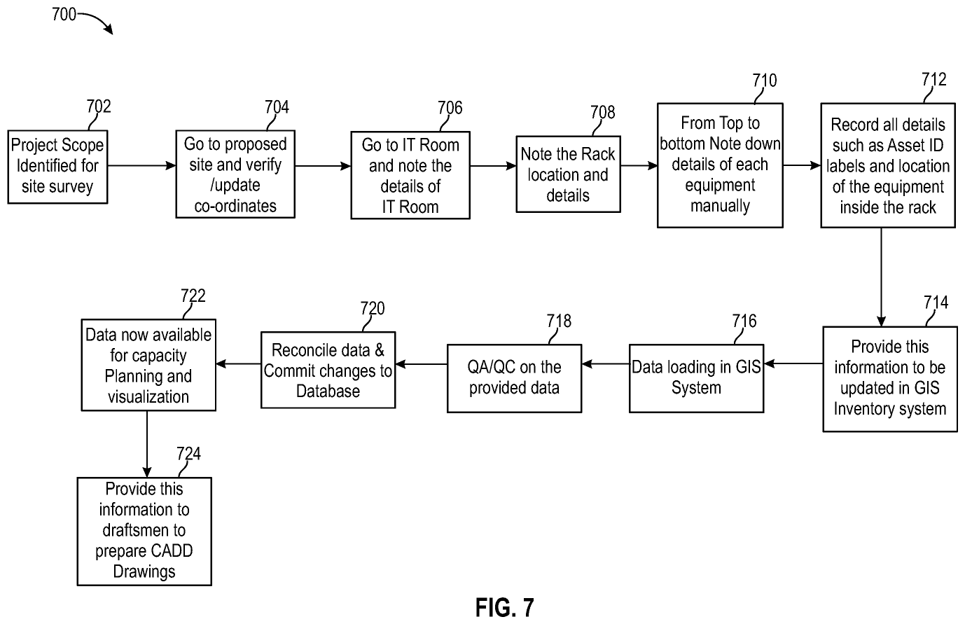

FIG. 7 is an example of a method 700 for IT infrastructure surveying and inventory management. The method 700 can begin at 702 by identifying a project scope for a site survey of an IT room, which can include identifying a building that includes the IT room (e.g., location information for a building that includes the IT room), and/or building information (e.g., building name or address). At 704, proceeding to the building and verifying location information for the building and/or building information, if needed, is performed. In some instances, the verifying can include updating location information for the building and/or building information. For example, a user can record updated information for the building, which can be used at a later a time to update an IT record for a site that includes an IT room. At 706, proceeding to the IT room in the building is performed. In some instances, the user can record an IT room number for updating or confirming that the IT record for the IT room is current in a database.

At 708, recording a rack label for each server rack in the IT room in the building is performed. At 710, identifying a respective server rack for recording server equipment information of the respective server rack is performed. At 712, recording server equipment information for one or more servers of the respective server rack is performed. The server equipment information can include asset identification information, model information, manufacturer information, IT room location information, building name, building number, hostname labels, connections, other indicia, location in the respective rack, etc. The recording can include front side and back side information to capture relevant server equipment information of the respective server rack.

At 714, providing the recorded server equipment information to a user for digitizing to convert the information into a digital format, referred to herein as server equipment data is performed. The digitizing can include inputting the recorded server equipment information into one or more excel or word processing documents to provide the server equipment data. Once converted to digital form, the server equipment data is ready to be provided to a GIS. At 716, loading the server equipment data into the GIS is performed. At 718, validating the server equipment data relative to the IT record for the site in the GIS is performed. At 720, reconciling the server equipment data and updating the server equipment data in response to identifying any changes between the server equipment data and the IT record for the site is performed. At 722, providing the IT record to a user to enable the user to use the IT record for capacity planning and visualization is performed. At 724, causing at least a portion of the IT infrastructure record to be provided to a draftsmen to prepare a CAD drawing for the IT room is performed. The CAD drawing can include relevant information from the server equipment data.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof. In addition, the use of ordinal numbers (e.g., first, second, third, etc.) is for distinction and not counting. For example, the use of “third” does not imply there must be a corresponding “first” or “second.” Also, as used herein, the terms “coupled” or “coupled to” or “connected” or “connected to” or “attached” or “attached to” may indicate establishing either a direct or indirect connection, and is not limited to either unless expressly referenced as such.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

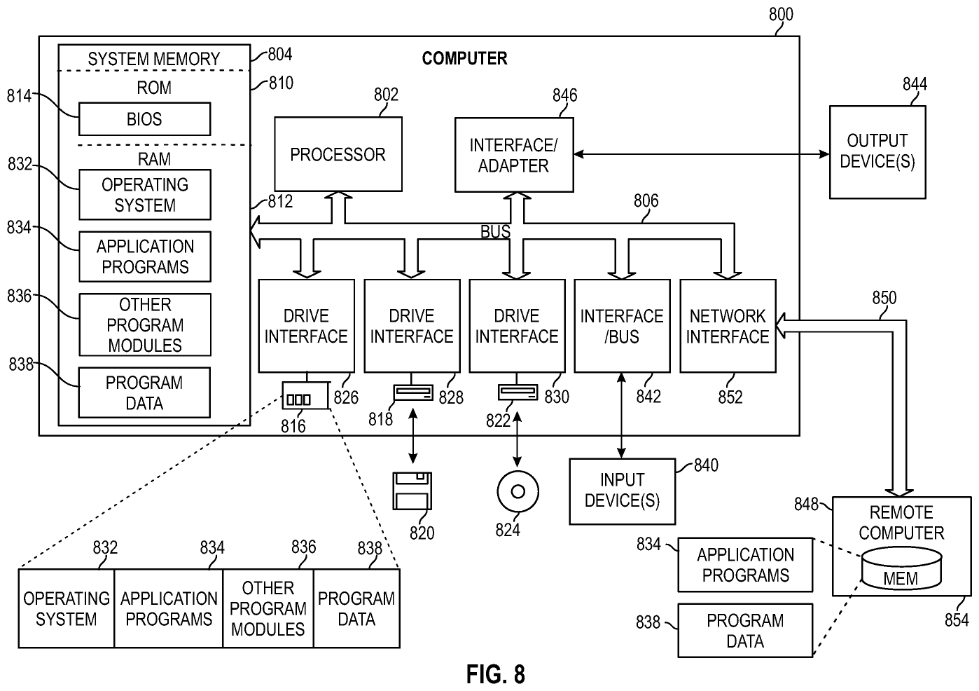

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 8. Furthermore, portions of the embodiments may be a computer program product on a computer-usable storage medium having computer readable program code on the medium. Any non-transitory, tangible storage media possessing structure may be utilized including, but not limited to, static and dynamic storage devices, hard disks, optical storage devices, and magnetic storage devices, but excludes any medium that is not eligible for patent protection under 35 U.S.C. § 101 (such as a propagating electrical or electromagnetic signal per se). As an example and not by way of limitation, a computer-readable storage media may include a semiconductor-based circuit or device or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. A computer-readable non-transitory storage medium may be volatile, nonvolatile, or a combination of volatile and non-volatile, where appropriate.

Certain embodiments have also been described herein with reference to block illustrations of methods, systems, and computer program products. It will be understood that blocks of the illustrations, and combinations of blocks in the illustrations, can be implemented by computer-executable instructions. These computer-executable instructions may be provided to one or more processor of a general purpose computer, special purpose computer, or other programmable data processing apparatus (or a combination of devices and circuits) to produce a machine, such that the instructions, which execute via the processor, implement the functions specified in the block or blocks.

These computer-executable instructions may also be stored in computer-readable memory that can direct a computer or other programmable data processing apparatus to function in a particular manner, such that the instructions stored in the computer-readable memory result in an article of manufacture including instructions which implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions specified in the flowchart block or blocks.

In this regard, FIG. 8 illustrates one example of a computer system 800 that can be employed to execute one or more embodiments of the present disclosure. Computer system 800 can be implemented on one or more general purpose networked computer systems, embedded computer systems, routers, switches, server devices, client devices, various intermediate devices/nodes or standalone computer systems. Additionally, computer system 800 can be implemented on various mobile clients such as, for example, a personal digital assistant (PDA), laptop computer, pager, and the like, provided it includes sufficient processing capabilities.

Computer system 800 includes processing unit 802, system memory 804, and system bus 806 that couples various system components, including the system memory 804, to processing unit 802. Dual microprocessors and other multi-processor architectures also can be used as processing unit 802. System bus 806 may be any of several types of bus structure including a memory bus or memory controller, a peripheral bus, and a local bus using any of a variety of bus architectures. System memory 804 includes read only memory (ROM) 810 and random access memory (RAM) 812. A basic input/output system (BIOS) 814 can reside in ROM 810 containing the basic routines that help to transfer information among elements within computer system 800.

Computer system 800 can include a hard disk drive 816, magnetic disk drive 818, e.g., to read from or write to removable disk 820, and an optical disk drive 822, e.g., for reading CD-ROM disk 824 or to read from or write to other optical media. Hard disk drive 816, magnetic disk drive 818, and optical disk drive 822 are connected to system bus 806 by a hard disk drive interface 826, a magnetic disk drive interface 828, and an optical drive interface 830, respectively. The drives and associated computer-readable media provide nonvolatile storage of data, data structures, and computer-executable instructions for computer system 800. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and described herein.

A number of program modules may be stored in drives and RAM 810, including operating system 832, one or more application programs 834, other program modules 836, and program data 838. In some examples, the application programs 834 can include the site surveyor 110, or the geospatial and image processing databases 124 and/or 126. The application programs 834 and program data 838 can include functions and methods programmed for IT infrastructure surveying and inventory management according to the examples described herein.

A user may enter commands and information into computer system 800 through one or more input devices 840, such as a pointing device (e.g., a mouse, touch screen), keyboard, microphone, joystick, game pad, scanner, and the like. These and other input devices are often connected to processing unit 802 through a corresponding port interface 842 that is coupled to the system bus, but may be connected by other interfaces, such as a parallel port, serial port, or universal serial bus (USB). One or more output devices 844 (e.g., display, a monitor, printer, projector, or other type of displaying device) is also connected to system bus 806 via interface 846, such as a video adapter.

Computer system 800 may operate in a networked environment using logical connections to one or more remote computers, such as remote computer 848. Remote computer 848 may be a workstation, computer system, router, peer device, or other common network node, and typically includes many or all the elements described relative to computer system 800. The logical connections, schematically indicated at 850, can include a local area network (LAN) and a wide area network (WAN). When used in a LAN networking environment, computer system 800 can be connected to the local network through a network interface or adapter 852. When used in a WAN networking environment, computer system 800 can include a modem, or can be connected to a communications server on the LAN. The modem, which may be internal or external, can be connected to system bus 806 via an appropriate port interface. In a networked environment, application programs 834 or program data 838 depicted relative to computer system 800, or portions thereof, may be stored in a remote memory storage device 854.

The invention claimed is:

1. A computer implemented method comprising:
receiving, by one or more processors, location information for a portable device located at a site having an information technology (IT) infrastructure with IT equipment;
identifying, by the one or more processors, geo-location data for the IT infrastructure and/or site based on the location information;
receiving, by the one or more processors, IT equipment data generated by a machine learning (ML) model based on one or more images of the IT equipment; and
mapping, by the one or more processors, the IT equipment data to an IT record to update the IT record for the site and/or IT infrastructure.

2. The computer implemented method of claim 1, further comprising generating, by the one or more processors, an IT drawing based on the updated record.

3. The computer implemented method of claim 2, further comprising causing, by the one or more processors, a printer to render the IT drawing on one or more papers.

4. The computer implemented method of claim 3, wherein the IT drawing is a computer aided design (CAD) drawing.

5. The computer implemented method of claim 1, further comprising causing, by the one or more processors, the geo-location data to be provided to the portable device.

6. The computer implemented method of claim 5, wherein the portable device includes a camera to capture the one or more images of the IT equipment after receiving the geo-location data.

7. The computer implemented method of claim 6, further comprising processing the one or more images using the ML model to identify IT equipment information therein and generating the IT equipment data using the identified IT equipment information.

8. The computer implemented method of claim 7, wherein the IT record is stored at a geospatial inventory database.

9. The computer implemented method of claim 7, wherein the geospatial inventory database is part of a geographic information system (GIS).

10. The computer implemented method of claim 9, wherein the mapping is based on a mapping model.

11. A system comprising:
memory to store machine-readable instructions and data; and
one or more processors to access the memory and execute the machine-readable instructions, the machine-readable instructions comprising:
a site surveyor that:
causes a network interface of a portable device to communicate location information for the portable device to a geospatial inventory database hosted by a computing system, the geospatial inventory database being configured to provide the site surveyor with geo-location data for an information technology (IT) infrastructure and/or site with IT equipment based on the location information of the portable device;
renders the geo-location data on a display of the portable device; and
causes a camera of the mobile device to capture one or more images of the IT equipment; and
an image processing database comprising a machine learning (ML) model that:
processes the one or more images of the IT equipment to identify IT equipment information therein;
generates IT equipment data using the identified IT equipment information; and
causes an IT record of the geospatial inventory database for the site and/or IT infrastructure to be updated based on the IT equipment data.

12. The system of claim 11, further comprising the geospatial inventory database, the geospatial inventory database to map the IT equipment data to the IT record to update the IT record for the IT infrastructure and/or site.

13. The system of claim 11, wherein the geospatial inventory database is to generate an IT drawing based on the updated record.

14. The system of claim 12, wherein the geospatial inventory database is to cause a printer to render the IT drawing on one or more papers.

15. The system of claim 14, wherein the IT drawing is a computer aided design (CAD) drawing.
